(19) United States
(12) Patent Application Publication
(10) Pub. No.: US 2020/0214124 A1
(43) Pub. Date: Jul. 2, 2020

(54) PRINTED CIRCUIT BOARD STRUCTURE INCLUDING FUSIBLE GROUND PLANE

(71) Applicant: Continental Automotive Systems Inc., Auburn Hills, MI (US)

(72) Inventors: Wilfredo Martinez, Lake Orion, MI (US); James Paul Muccioli, White Lake, MI (US); Nicholas Scott Hartley, Shelby Twp., MI (US)

(21) Appl. No.: 16/413,069

(22) Filed: May 15, 2019

Related U.S. Application Data
(60) Provisional application No. 62/785,793, filed on Dec. 28, 2018.

(51) Int. Cl. H05K 1/02

(52) U.S. Cl. CPC H05K 1/0293; H05K 1/0215; H05K 1/0207

(57) ABSTRACT

An example printed circuit board includes a ground plane having a fusible region and a power plane. The power plane is isolated from the ground plane by an insulating layer. At least one circuit component is mounted to the ground plane and is positioned within the fusible region of the printed circuit board.

### CROSS-REFERENCE TO RELATED APPLICATION

This application claims priority to U.S. Provisional Patent Application No. 62/785,793 filed on Dec. 28, 2018.

### TECHNICAL FIELD

The present disclosure relates generally to printed circuit board structures, and more specifically fusible ground plane structures for printed circuit boards.

### BACKGROUND

Electronic controllers, and other electronic devices that utilize printed circuit board (PCB) technology, typically include at least a power plane and a ground plane separated by an insulating material within the PCB. Alternative constructions can include additional power planes and ground planes, with the increasing number of power planes and ground planes dictating a corresponding decrease in the thickness of each layer. Such constructions can experience an error condition where the power plane of the PCB and the ground plane of the PCB are shorted together.

This can occur when capacitors, power integrated circuits (ICs), or any similar components mounted to the PCB experience certain types of faults. When such a fault occurs, it is possible for the PCB to experience a large destruction event due to the substantial current levels passing through the ground plane, and it is easy for thermal damage to propagate through the planes of the PCB due to the high current capacity.

### SUMMARY OF THE INVENTION

In one exemplary embodiment a printed circuit board includes a ground plane including a fusible region, a power plane isolated from the ground plane by an insulating layer, and at least one circuit component mounted to the ground plane within the fusible region.

In another example of the above described printed circuit board the fusible region is a mesh pad mounted to a solid ground plane body.

Another example of any of the above described printed circuit boards further includes an insulating pad disposed between a majority of the mesh pad and the solid ground plane body.

In another example of any of the above described printed circuit boards the mesh pad is a consistent material configuration.

In another example of any of the above described printed circuit boards the mesh pad includes a first material in a first fusible configuration and a second material in a second non-fusible configuration, and wherein the second material is surrounded by the first material.

In another example of any of the above described printed circuit boards the first material and the second material have a distinct material composition.

In another example of any of the above described printed circuit boards the ground plan includes a mesh grid connected to the insulating layer.

In another example of any of the above described printed circuit boards an entirety of the mesh grid is fusible.

In another example of any of the above described printed circuit boards at least one region of the mesh grid is surrounded by fusible portions of the mesh grid.

In another example of any of the above described printed circuit boards rein the ground plane consists of the mesh grid.

In another example of any of the above described printed circuit boards the fusible region is a mesh grid embedded in a solid ground plane.

In another example of any of the above described printed circuit boards the mesh grid comprises multiple grid lines, and each line of the mesh grid is fusible.

In another example of any of the above described printed circuit boards at least a portion of the mesh grid is non-fusible, and wherein the non-fusible portion is surrounded by a fusible portion of the mesh grid.

Another example of any of the above described printed circuit boards further includes at least one additional power plane and at least one additional ground plane.

An exemplary method for preventing propagation of short circuits on a printed circuit board includes defining a least a portion of a ground plane using a fusible mesh grid, and disconnecting a sub-portion of the fusible mesh grid from a remainder of the ground plane via fuse action when a short circuit is present.

In another example of the above described exemplary method for preventing propagation of short circuits on a printed circuit board defining at least the portion of the ground plane using the fusible mesh grid comprises disposing a mesh grid pad on a solid ground plane body.

In another example of any of the above described exemplary methods for preventing propagation of short circuits on a printed circuit board defining at least a portion of the ground plane using the fusible mesh grid comprises embedding a mesh grid portion within a ground plane body.

In another example of any of the above described exemplary methods for preventing propagation of short circuits on a printed circuit board defining at least the portion of the ground plane using the fusible mesh grid comprises constructing an entirety of the ground plane using the fusible mesh grid.

In another example of any of the above described exemplary methods for preventing propagation of short circuits on a printed circuit board the fusible mesh grid is entirely fusible.

In another example of any of the above described exemplary methods for preventing propagation of short circuits on a printed circuit board the fusible mesh grid includes an exterior circumference, and the exterior circumference is fusible.

These and other features of the present invention can be best understood from the following specification and drawings, the following of which is a brief description.

### BRIEF DESCRIPTION OF THE DRAWINGS

FIG. 1 illustrates a side view of an exemplary printed circuit board (PCB).

FIG. 2A schematically illustrates a top view of a first example ground plane.

FIG. 2B schematically illustrates a side view of the first example ground plane.

FIG. 2C schematically illustrates a top view of the first example ground plane after a short circuit event.

FIG. 3A schematically illustrates a top view of second example ground plane.

FIG. 3B schematically illustrates a side view of the second example ground plane.

FIG. 3C schematically illustrates a top view of the second example ground plane after a short circuit event.

FIG. 4A schematically illustrates a top view of a third example ground plane.

FIG. 4B schematically illustrates a side view of the third example ground plane.

FIG. 4C schematically illustrates a top view of the third example ground plane after a short circuit event.

### DETAILED DESCRIPTION

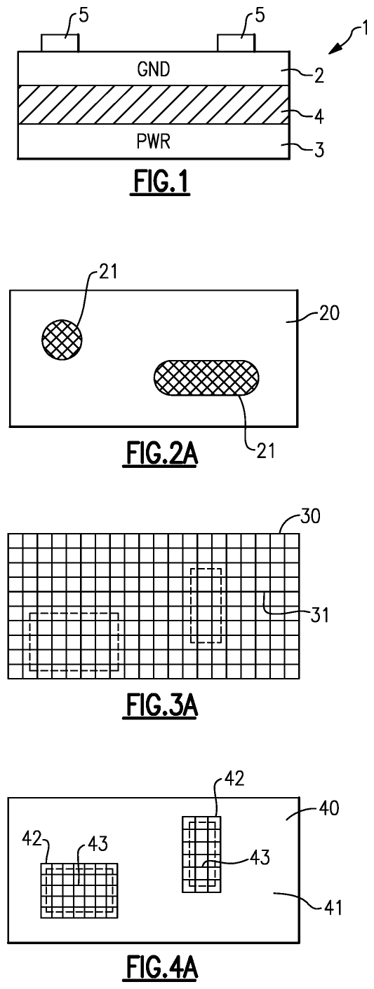

FIG. 1 schematically illustrates an exemplary printed circuit board (PCB) 1 including a ground layer 2 (GND) and a power layer 3 (PWR) separated by an insulating layer 4. Circuit components 5 are mounted to the ground layer 2, and connected through the insulating layer 4 to the power layer 3 according to any known or conventional PCB construction technique. It is further understood that the three layer 2, 3, 4 construction of the PCB 1 is exemplary, and the teachings herein can be extended to a PCB including any number of layers where the ground layer 2 is isolated from the power layer 3. By way of example, PCB's including 4, 6, 8 or 12 layers can be utilized with the same techniques described herein.

When a short circuit occurs between the ground layer 2 and the power layer 3, large amounts of current pass through the power layer 3 to the ground layer 2. The large amounts of current, in turn, generate large amounts of heat that can damage or destroy large sections of the PCB 1 if they are allowed to propagate. Short circuits, such as those described herein, can occur via a fault in a power component or due to mechanical stresses on the PCB 1. In the event of mechanical stresses, the fault can occur even absent the presence of the circuit components 5.

In order to mitigate the damage caused when a short between the ground layer 2 and the power layer 3 occurs, the conventional solid ground layer 2 can be entirely, or partially, replaced with a mesh grid when the mesh is configured to operate as a fuse and open (disconnect) when a high current occurs, while still maintaining high EMC efficiency. This configuration is referred to as a fusible mesh grid. In another example, the fusible mesh grid can be applied to the solid ground layer 2, with circuit components 5 mounted to the fusible mesh grid.

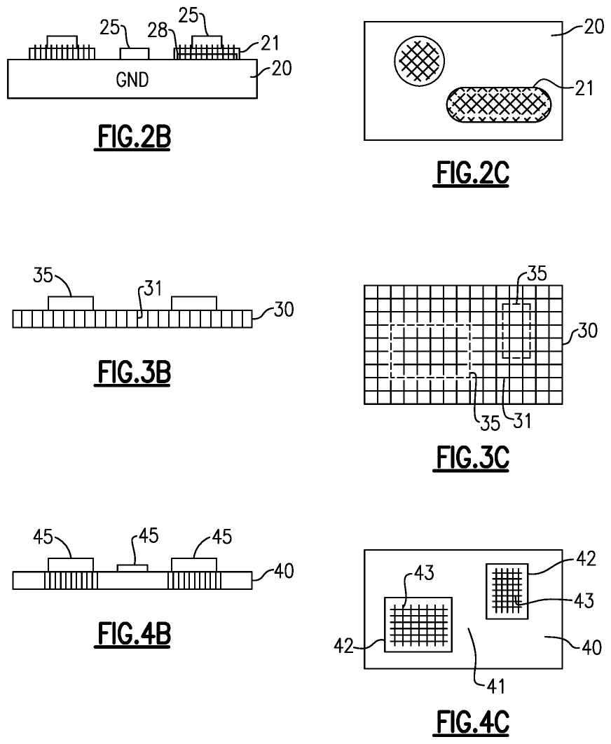

With continued reference to FIG. 1, FIG. 2A illustrates a top view of a ground plane 20 incorporating a first exemplary implementation of a mesh grid 21. FIG. 2B illustrates a side view of the ground plane 20 of FIG. 2A. FIG. 2C illustrates a second top view of the ground plane 20 after a short circuit has occurred and the fusible mesh grid 21 has been broken.

In the example of FIGS. 2A-2C, the ground plane 20 is a solid ground plane and the mesh grids 21 are small fusible grids mounted to the solid ground plane 21, and positioned only in important areas of the printed circuit board. In some examples, a pad 28 can be disposed between the fusible mesh grid 21 and the ground plane 20 in order to support the fusible mesh grid 21 and any circuit components 25 mounted to the fusible mesh grid 21. The mounted components 25 (e.g. the components 5 of FIG. 1) within the important areas are mounted to the fusible mesh grids 21. During operation, if a short circuit event occurs on the ground plane 20, the fusible nature of the mesh grids 21 operates as a fuse and severs connection with the ground plane 20 thereby isolating the ground plane 21 from the circuit components 25 mounted to the fusible mesh grid 21. This fusible operation prevents the high current from passing through the important region, thereby protecting the important region from resulting thermal breakdowns.

FIG. 2C illustrates the broken connections at each of the mesh grids 21. Since the mesh grids 21 are no longer connected to the ground plane 20 after the fuse occurs, any circuit components mounted on the mesh grid 21 are isolated from the ground event and short circuit currents can be prevented from propagating.

With continued reference to FIGS. 1 and 2A-2C, FIG. 3A schematically illustrates a top view of a ground plane 30 comprised entirely of a fusible mesh grid 31, with the fusible mesh grid 31 being configured to exhibit a high efficiency EMC performance. FIG. 3B illustrates a side view of the fusible mesh grid 31. This configuration allows circuit components disposed at other areas of the ground plane 21 to continue operations as the connections around the short circuit are fused out and the short circuited component or portion is isolated form the remainder of the ground plane 20.

As with the example of FIGS. 2A-2C, when a short circuit between the ground plane 30 and the power plane (e.g. power plane 3 in FIG. 1) occurs, the mesh at the location of the short circuit destructs, resulting in an open fuse. The open fuse severs the short circuit and the short circuit is prevented from propagating.

With continued reference to FIGS. 1-3C, FIG. 4A schematically illustrates a top view of an exemplary ground plane 40 that incorporates the features of each of the ground plane 20 of FIG. 2 and the ground plane 30 of FIG. 3. The ground plane 40 includes a majority solid ground plane structure 41. Embedded within the solid ground plane structure 41, and replacing the solid ground plane structure 41 at designated important regions 42, is a fusible mesh grid 43. The fusible mesh grid 43 maximizes both the concepts of FIGS. 2 and 3 by providing the solid ground plane 41 under areas where very high speed ICs (e.g. microprocessors) are positioned, and providing the fusible mesh grid 43 under areas 42 where power components or other circuit components that may be susceptible to short circuiting are positioned.

With reference to all of FIGS. 1-4C, when a short circuit occurs, the short circuit continuously seeks out the most direct pathway to ground. As a result of the continuous routing, an isolation boundary is fused out around the circuit component causing the short circuit (as illustrated in FIGS. 2C, 3C and 4C), while leaving a remainder of the components and ground plane connected.

In some examples, the entirety of the mesh grid 21, 31, 41 can be constructed of a single material, with the material being disposed on the ground plan in a manner that will fuse when excess current is passed through the material. In alternate examples, portions of the mesh can be non-fusible, and only segments surrounding select circuit components can be constructed of the fusible material or in the fusible configuration.

Further, it is appreciated that the alternate examples can be used independently or in conjunction with each other in any given embodiment, and the ground plane constructions are not mutually exclusive.

It is further understood that any of the above described concepts can be used alone or in combination with any or all of the other above described concepts. Although an embodiment of this invention has been disclosed, a worker of ordinary skill in this art would recognize that certain modifications would come within the scope of this invention. For that reason, the following claims should be studied to determine the true scope and content of this invention.

1. A printed circuit board comprising:
a ground plane including a fusible region;
a power plane isolated from the ground plane by an insulating layer; and
at least one circuit component mounted to the ground plane within the fusible region.

2. The printed circuit board of claim 1, wherein the fusible region is a mesh pad mounted to a solid ground plane body.

3. The printed circuit board of claim 2, further comprising an insulating pad disposed between a majority of the mesh pad and the solid ground plane body.

4. The printed circuit board of claim 2, wherein the mesh pad is a consistent material configuration.

5. The printed circuit board of claim 2, wherein the mesh pad includes a first material in a first fusible configuration and a second material in a second non-fusible configuration, and wherein the second material is surrounded by the first material.

6. The printed circuit board of claim 5, wherein the first material and the second material have a distinct material composition.

7. The printed circuit board of claim 1, wherein the ground plan includes a mesh grid connected to the insulating layer.

8. The printed circuit board of claim 7, wherein an entirety of the mesh grid is fusible.

9. The printed circuit board of claim 7, wherein at least one region of the mesh grid is surrounded by fusible portions of the mesh grid.

10. The printed circuit board of claim 7, wherein the ground plane consists of the mesh grid.

11. The printed circuit board of claim 1, wherein the fusible region is a mesh grid embedded in a solid ground plane.

12. The printed circuit board of claim 11, wherein the mesh grid comprises multiple grid lines, and each line of the mesh grid is fusible.

13. The printed circuit board of claim 11, wherein at least a portion of the mesh grid is non-fusible, and wherein the non-fusible portion is surrounded by a fusible portion of the mesh grid.

14. The printed circuit board of claim 1, further comprising at least one additional power plane and at least one additional ground plane.

15. A method for preventing propagation of short circuits on a printed circuit board comprising;
defining a least a portion of a ground plane using a fusible mesh grid; and
disconnecting a sub-portion of the fusible mesh grid from a remainder of the ground plane via fuse action when a short circuit is present.

16. The method of claim 15, wherein defining at least the portion of the ground plane using the fusible mesh grid comprises disposing a mesh grid pad on a solid ground plane body.

17. The method of claim 15, wherein defining at least a portion of the ground plane using the fusible mesh grid comprises embedding a mesh grid portion within a ground plane body.

18. The method of claim 15, wherein defining at least the portion of the ground plane using the fusible mesh grid comprises constructing an entirety of the ground plane using the fusible mesh grid.

19. The method of claim 15, wherein the fusible mesh grid is entirely fusible.

20. The method of claim 15, wherein the fusible mesh grid includes an exterior circumference, and the exterior circumference is fusible.
